(19) United States
(12) Patent Application Publication
(10) Pub. No.: US 2025/0323676 A1
(43) Pub. Date: Oct. 16, 2025

(54) Electronic device and communication chip thereof

(71) Applicant: REALTEK SEMICONDUCTOR CORPORATION, HSINCHU (TW)

(72) Inventor: YI-CHANG SHIH, HSINCHU (TW)

(21) Appl. No.: 19/090,688

(22) Filed: Mar. 26, 2025

(30) Foreign Application Priority Data
Apr. 11, 2024 (TW) 113113620

(51) Int. Cl. H04B 1/40; H03M 1/66

(52) U.S. Cl. CPC H04B 1/40; H03M 1/66

(57) ABSTRACT

An electronic device is used to transmit a radio frequency (RF) output signal or receive an RF input signal and includes an antenna and a communication chip. The communication chip includes a pin, an impedance matching circuit, a digital baseband circuit, a reference signal generation circuit, a transmitter circuit, and a receiver circuit. The pin is electrically connected to the antenna. The impedance matching circuit is coupled to the pin. The reference signal generation circuit is coupled to the digital baseband circuit. The transmitter circuit is used to generate the RF output signal. The receiver circuit is used to process the RF input signal. The communication chip transmits the RF output signal through the pin or receives the RF input signal through the pin.

### BACKGROUND OF THE INVENTION

### 1. Field of the Invention

The present invention generally relates to an electronic device, and, more particularly, to an electronic device that supports at least two modulation schemes and shares an antenna.

### 2. Description of Related Art

FIG. 1 shows a functional block diagram of a conventional electronic device 100. The electronic device 100 includes a communication chip 110, a switch 120, and an antenna 130. The communication chip 110 includes a two-point modulation (TPM) transceiver 112, an in-phase quadrature modulation (IQM) transceiver 114, and a digital baseband circuit 116. The communication chip 110, the switch 120, and the antenna 130 are disposed on a circuit board.

The communication chip 110 provides two modulation schemes (i.e., TPM and IQM), and the two modulation schemes share the antenna 130. The antenna 130 is coupled to a pin 111a or a pin 111b through the switch 120, and the pin 111a and the pin 111b are respectively coupled to the TPM transceiver 112 and the IQM transceiver 114.

The electronic device 100 has the following disadvantages: (1) the communication chip 110 has a large area (because there are two independent transceivers); and (2) the switch 120 causes an increase in cost (because the sharing of the antenna 130 requires the switch 120).

### SUMMARY OF THE INVENTION

In view of the issues of the prior art, an object of the present invention is to provide an electronic device and its communication chip, so as to make an improvement to the prior art.

According to one aspect of the present invention, a communication chip is provided. The communication chip is configured to transmit a radio frequency (RF) output signal and includes a digital baseband circuit, a reference signal generation circuit, a digital-to-analog converter (DAC), a filter circuit, and a transmitter front-end circuit. The digital baseband circuit is configured to generate a control signal and a digital output signal. The reference signal generation circuit is coupled to the digital baseband circuit and is configured to generate a reference signal. The DAC is coupled to the digital baseband circuit and is configured to convert the digital output signal into an analog output signal. The filter circuit is coupled to the DAC and is configured to filter the analog output signal to generate a filtered analog output signal. The transmitter front-end circuit is coupled to the filter circuit. When the communication chip operates in a first mode, the transmitter front-end circuit up-converts and amplifies the filtered analog output signal according to the reference signal to generate the RF output signal. When the communication chip operates in a second mode, the reference signal generation circuit changes the frequency of the reference signal according to the control signal, and the transmitter front-end circuit amplifies the reference signal to generate the RF output signal.

According to another aspect of the present invention, a communication chip is provided. The communication chip is configured to transmit a radio frequency (RF) output signal or receive an RF input signal, and includes an impedance matching circuit, a pin, a digital baseband circuit, a reference signal generation circuit, a digital-to-analog converter (DAC), a filter circuit, a transmitter front-end circuit, and a receiver circuit. The pin is coupled to the impedance matching circuit. The digital baseband circuit is configured to generate a control signal and a digital output signal. The reference signal generation circuit is coupled to the digital baseband circuit and is configured to generate a reference signal. The DAC is coupled to the digital baseband circuit and is configured to convert the digital output signal into an analog output signal. The filter circuit is coupled to the DAC and is configured to filter the analog output signal to generate a filtered analog output signal. The transmitter front-end circuit is coupled to the filter circuit and the impedance matching circuit and is configured to process the filtered analog output signal or the reference signal to generate the RF output signal, and transmit the RF output signal through the impedance matching circuit and the pin. The receiver circuit is coupled to the impedance matching circuit and is configured to receive the RF input signal through the pin and the impedance matching circuit.

According to still another aspect of the present invention, an electronic device is provided. The electronic device is configured to transmit a radio frequency (RF) output signal or receive an RF input signal, and includes an antenna and a communication chip. The communication chip includes a pin, an impedance matching circuit, a digital baseband circuit, a reference signal generation circuit, a transmitter circuit, and a receiver circuit. The pin is electrically connected to the antenna. The impedance matching circuit is coupled to the pin. The reference signal generation circuit is coupled to the digital baseband circuit. The transmitter circuit is coupled to the digital baseband circuit, the reference signal generation circuit, and the impedance matching circuit and is configured to generate the RF output signal. The receiver circuit is coupled to the digital baseband circuit, the reference signal generation circuit, and the impedance matching circuit and is configured to process the RF input signal. The communication chip transmits the RF output signal through the pin or receives the RF input signal through the pin.

The technical means embodied in the embodiments of the present invention can solve at least one of the problems of the prior art. Therefore, compared to the prior art, the present invention can reduce area and cost.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 shows a functional block diagram of a conventional electronic device.

FIG. 2 is the functional block diagram of the electronic device according to an embodiment of the present invention.

FIG. 3 is a detailed functional block diagram of the communication chip according to an embodiment of the present invention.

FIG. 4 shows the connections among the impedance matching circuit, the power amplifier driver (PAD), and the power amplifier of FIG. 3 according to an embodiment.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes an electronic device and its communication chip. On account of that some or all elements of the electronic device and its communication chip could be known, the detail of such elements is omitted provided that such detail has little to do with the features of this disclosure, and that this omission nowhere dissatisfies the specification and enablement requirements. A person having ordinary skill in the art can choose components or steps equivalent to those described in this specification to carry out the present invention, which means that the scope of this invention is not limited to the embodiments in the specification.

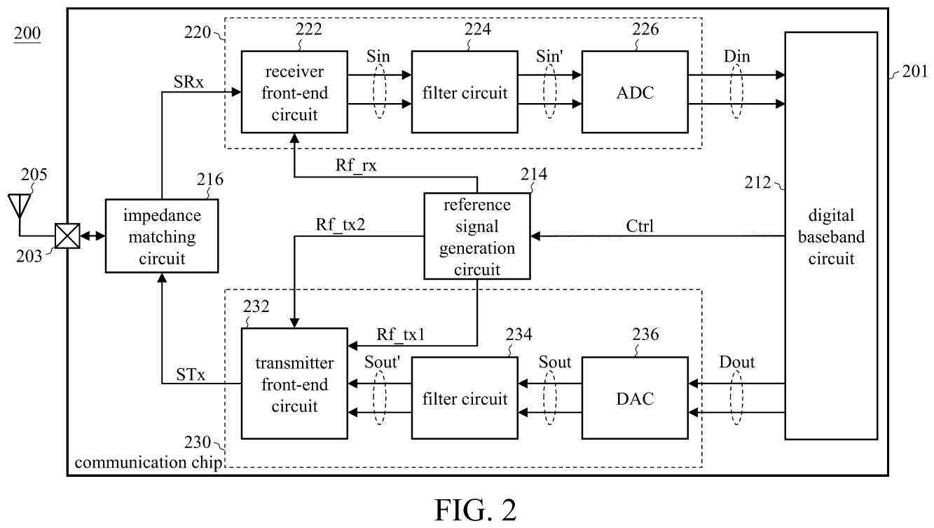

Reference is made to FIG. 2, which is a functional block diagram of the electronic device according to an embodiment of the present invention. The electronic device 200 includes a communication chip 201 and an antenna 205. The communication chip 201 includes a pin 203, a digital baseband circuit 212, a reference signal generation circuit 214, an impedance matching circuit 216, a receiver circuit 220, and a transmitter circuit 230. The receiver circuit 220 includes a receiver front-end circuit 222, a filter circuit 224, and an analog-to-digital converter (ADC) 226. The transmitter circuit 230 includes a transmitter front-end circuit 232, a filter circuit 234, and a digital-to-analog converter (DAC) 236. The impedance matching circuit 216 is used for implementing the impedance matching of the transmission line. The filter circuit 224 and the filter circuit 234 may be a complex filter or a low-pass filter (LPF). The communication chip 201 is coupled to the antenna 205 through the pin 203.

The digital baseband circuit 212 is coupled or electrically connected to the reference signal generation circuit 214, the receiver circuit 220, and the transmitter circuit 230. For the transmitter circuit 230 (more specifically, for the transmitter front-end circuit 232), the reference signal generation circuit 214 generates a reference signal Rf_tx1 in the in-phase quadrature modulation (IQM) mode, and generates a reference signal Rf_tx2 in the two-point modulation (TPM) mode. For the receiver circuit 220 (more specifically, for the receiver front-end circuit 222), the reference signal generation circuit 214 generates a reference signal Rf_rx in both the IQM mode and the TPM mode, and the frequency of the reference signal Rf_rx in the IQM mode can be equal to or not equal to the frequency in the TPM mode.

The digital baseband circuit 212 generates a control signal Ctrl and a digital output signal Dout. The digital baseband circuit 212 uses the control signal Ctrl to control the reference signal generation circuit 214 to set or adjust (change) the frequency of the reference signal Rf_tx1 and/or the frequency of the reference signal Rf_tx2. In the IQM mode, the frequency of the reference signal Rf_tx1 is fixed (i.e., the reference signal Rf_tx1 is a single tone signal). In the TPM mode, the digital baseband circuit 212 performs frequency modulation (FM) on the reference signal Rf_tx2 through the control signal Ctrl (equivalent to performing frequency modulation on the radio frequency (RF) output signal STx), that is, changing the frequency of the reference signal Rf_tx2.

In the IQM mode, the transmitter circuit 230 converts the digital output signal Dout generated by the digital baseband circuit 212 into the RF output signal STx. The RF output signal STx is coupled to the antenna 205 via the impedance matching circuit 216 and the pin 203. More specifically, the DAC 236 converts the digital output signal Dout into the analog output signal Sout. The filter circuit 234 filters the analog output signal Sout to generate the filtered analog output signal Sout′. The transmitter front-end circuit 232 up-converts and amplifies the filtered analog output signal Sout′ according to the reference signal Rf_tx1 to generate the RF output signal STx.

In the TPM mode, the filter circuit 234 and the DAC 236 are inactive, while the transmitter front-end circuit 232 amplifies the reference signal Rf_tx2 to generate the RF output signal STx. The RF output signal STx is coupled to the antenna 205 via the impedance matching circuit 216 and the pin 203.

The receiver circuit 220 converts the RF input signal SRx, which the communication chip 201 receives through the antenna 205 and the pin 203, into the digital input signal Din. More specifically, the receiver front-end circuit 222 down-converts the RF input signal SRx according to the reference signal Rf_rx to generate the analog input signal Sin. The filter circuit 224 filters the analog input signal Sin to generate the filtered analog input signal Sin′. The ADC 226 converts the filtered analog input signal Sin′ into the digital input signal Din.

Due to the shared use of the impedance matching circuit 216 by the receiver circuit 220 and the transmitter circuit 230, the communication chip 201 can transmit the RF output signal STx or receive the RF input signal SRx through the same pin (i.e., the pin 203). Furthermore, because the receiver circuit 220 and the transmitter circuit 230 share the pin 203, the antenna 205 does not need to switch between two pins. In other words, the pin 203 and the antenna 205 can be electrically connected to each other, thereby eliminating the need for the prior-art switch 120 and further reducing the costs.

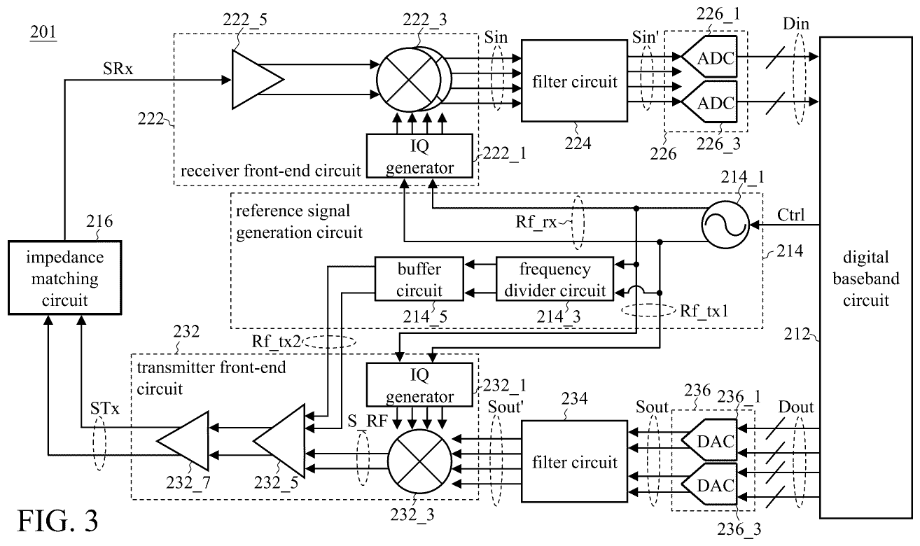

Reference is made to FIG. 3, which is a detailed functional block diagram of the communication chip 201 according to an embodiment of the present invention. The reference signal generation circuit 214 includes a synthesizer 214_1, a frequency divider circuit 214_3, and a buffer circuit 214_5. The receiver front-end circuit 222 includes an in-phase quadrature generator (IQ generator) 222_1, a mixer circuit 222_3, and a low noise amplifier (LNA) 222_5. The ADC 226 includes an ADC 226_1 and an ADC 226_3. The transmitter front-end circuit 232 includes an IQ generator 232_1, a mixer circuit 232_3, a power amplifier driver (PAD) 232_5, and a power amplifier 232_7. The DAC 236 includes a DAC 236_1 and a DAC 236_3. The IQM mode and the TPM mode are respectively discussed as follows.

### Mode (1): The IQM Mode.

The synthesizer 214_1 generates the reference signal Rf_tx1 with a fixed frequency (i.e., the reference signal Rf_tx1 is a single tone signal), and the frequency divider circuit 214_3 and the buffer circuit 214_5 are inactive or disabled (in other words, in the IQM mode, the reference signal Rf_tx2 does not exist). More specifically, the digital baseband circuit 212 sets the frequency of the reference signal Rf_tx1 with the control signal Ctrl, and then the synthesizer 214_1 operates at that frequency afterwards. Alternatively, the synthesizer 214_1 operates at a default frequency (i.e., the frequency of the reference signal Rf_tx1) without being controlled by the control signal Ctrl.

In some embodiments, the control signal Ctrl is a digital signal, and the synthesizer 214_1 is a digitally controlled synthesizer (e.g., including a digital controlled oscillator (DCO)).

When the communication chip 201 transmits a signal, the IQ generator 232_1 generates an in-phase signal and a quadrature signal based on the reference signal Rf_tx1, and the mixer circuit 232_3 up-converts the filtered analog output signal Sout′ based on the in-phase signal and the quadrature signal to generate the RF signal S_RF. The RF signal S_RF is amplified by the PAD 232_5 and the power amplifier 232_7 to generate the RF output signal STx.

When the communication chip 201 receives a signal, the synthesizer 214_1 generates the reference signal Rf_rx, the IQ generator 222_1 generates an in-phase signal and a quadrature signal based on the reference signal Rf_rx, and the mixer circuit 222_3 down-converts the output signal of the LNA 222_5 based on the in-phase signal and the quadrature signal to generate the analog input signal Sin.

### Mode (2): The TPM Mode.

When the communication chip 201 transmits a signal, the digital baseband circuit 212 controls the synthesizer 214_1 with the control signal Ctrl to change the frequencies of the reference signal Rf_tx1 and the reference signal Rf_tx2, in order to achieve the purpose of frequency modulation of the RF output signal STx. The reference signal Rf_tx2 is the signal resulting from the processing of the reference signal Rf_tx1 by the frequency divider circuit 214_3 and the buffer circuit 214_5. The PAD 232_5 and the power amplifier 232_7 amplify the reference signal Rf_tx2 to generate the RF output signal STx. The purpose of the frequency divider circuit 214_3 is to make the frequency of the RF output signal STx not equal to the frequency of the reference signal Rf_tx1, so as to prevent the large power of the RF output signal STx from affecting the operation of the synthesizer 214_1 when the RF output signal STx and the reference signal Rf_tx1 are at the same frequency. The purpose of the buffer circuit 214_5 is to enhance the power of the signal to counter the signal attenuation on the transmission line.

In some embodiments, if the power of the RF output signal STx is relatively small or the synthesizer 214_1 is relatively ideal, then the frequency divider circuit 214_3 can be omitted.

In some embodiments, if the signal attenuation on the transmission line is relatively small, the buffer circuit 214_5 can be omitted.

The operation of the receiver front-end circuit 222 in the TPM mode is the same as the operation in the IQM mode, so further elaboration is omitted for brevity. It should be noted that when the communication chip 201 receives a signal, whether in the IQM mode or TPM mode, the reference signal Rf_rx is a single tone signal. In other words, the digital baseband circuit 212 does not perform frequency modulation on the reference signal Rf_rx.

It can be known from above that, in the TPM mode, the digital baseband circuit 212 modulates the frequency of the reference signal Rf_tx1 (equivalent to modulating the frequency of the reference signal Rf_tx2 and the RF output signal STx) through the control signal Ctrl.

In some embodiments, since the IQ generator 232_1, the mixer circuit 232_3, the filter circuit 234, and the DAC 236 are inactive in the TPM mode, the digital baseband circuit 212 can turn off or disable these components to save power.

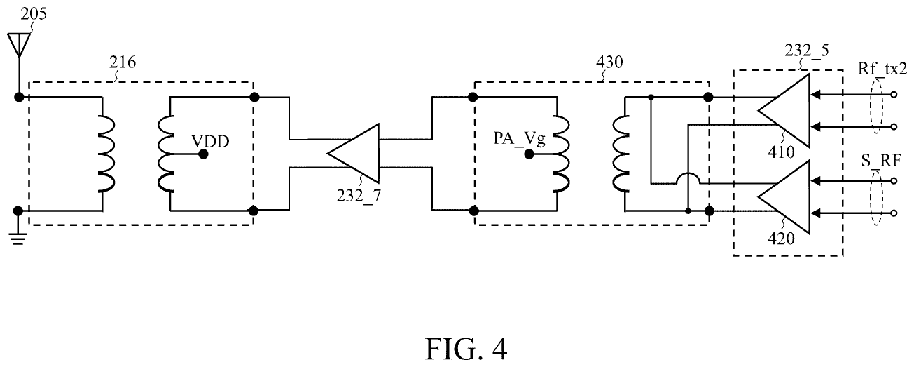

Reference is made to FIG. 4, which shows an embodiment of the connections among the impedance matching circuit 216, the PAD 232_5, and the power amplifier 232_7 in FIG. 3. In the embodiment of FIG. 4, the impedance matching circuit 216 is a transformer, and the transmitter front-end circuit 232, in addition to including the PAD 232_5 and the power amplifier 232_7, also includes a transformer 430. The PAD 232_5 includes a sub-PAD 410 and a sub-PAD 420, which are used to process (e.g., amplify) the reference signal Rf_tx2 and the RF signal S_RF, respectively. The primary side of the transformer 430 is coupled or electrically connected to the sub-PAD 410 and the sub-PAD 420, while the secondary side is coupled or electrically connected to the power amplifier 232_7. The voltage PA_Vg is the gate bias of the main transistor of the power amplifier 232_7. The primary side of the impedance matching circuit 216 is coupled or electrically connected to the power amplifier 232_7, while the secondary side is coupled or electrically connected to the antenna 205. The voltage VDD is the power supply voltage of the power amplifier 232_7.

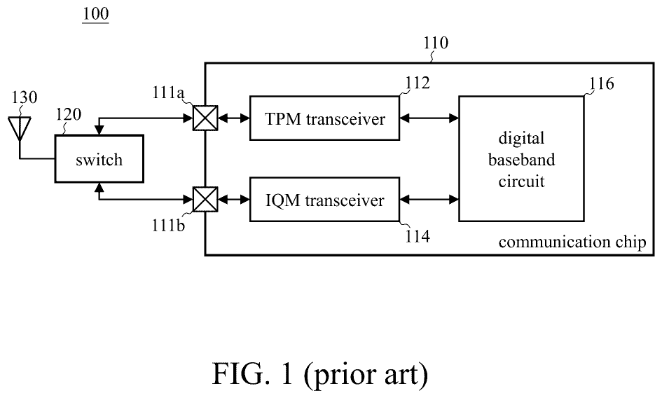

In summary, the communication chip 201 of the present invention supports the IQM mode and the TPM mode, and both modes share the impedance matching circuit 216, the receiver front-end circuit 222, the filter circuit 224, the ADC 226, part of the reference signal generation circuit 214, and part of the transmitter front-end circuit 232. Therefore, compared to the conventional technology, the communication chip 201 of the present invention has the following advantages: (1) saving area (because of shared components); and (2) the switch 120 from the prior-art circuit (see FIG. 1) does not need to be set on the circuit board (because both modes share the pin 203).

The TPM and the IQM are intended to illustrate the invention by way of example and not to limit the scope of the claimed invention. People having ordinary skill in the art may apply the present invention to other types of modulation schemes in accordance with the foregoing discussions.

Note that the shape, size, and ratio of any element in the disclosed figures are exemplary for understanding, not for limiting the scope of this invention.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A communication chip configured to transmit a radio frequency (RF) output signal, comprising:
a digital baseband circuit configured to generate a control signal and a digital output signal;
a reference signal generation circuit coupled to the digital baseband circuit and configured to generate a reference signal;
a digital-to-analog converter (DAC) coupled to the digital baseband circuit and configured to convert the digital output signal into an analog output signal;
a filter circuit coupled to the DAC and configured to filter the analog output signal to generate a filtered analog output signal; and
a transmitter front-end circuit coupled to the filter circuit;
wherein when the communication chip operates in a first mode, the transmitter front-end circuit up-converts and amplifies the filtered analog output signal according to the reference signal to generate the RF output signal; and
wherein when the communication chip operates in a second mode, the reference signal generation circuit changes a frequency of the reference signal according to the control signal, and the transmitter front-end circuit amplifies the reference signal to generate the RF output signal.

2. The communication chip of claim 1, wherein when the communication chip operates in the first mode, the reference signal is a single tone signal.

3. The communication chip of claim 1, further comprising:
an impedance matching circuit coupled to the transmitter front-end circuit;
a pin coupled to the impedance matching circuit; and
a receiver circuit coupled to the impedance matching circuit and configured to receive an RF input signal through the pin and the impedance matching circuit;
wherein the transmitter front-end circuit transmits the RF output signal through the impedance matching circuit and the pin.

4. The communication chip of claim 1, wherein the transmitter front-end circuit comprises:
a mixer circuit coupled to the filter circuit and configured to up-convert the filtered analog output signal to generate an RF signal;
a power amplifier driver (PAD) coupled to the mixer circuit and comprising:
a first sub-PAD coupled to the mixer circuit and configured to amplify the reference signal; and
a second sub-PAD coupled to the mixer circuit and configured to amplify the RF signal;
a power amplifier; and
a transformer coupled between the PAD and the power amplifier.

5. The communication chip of claim 4, wherein the digital baseband circuit disables the DAC, the filter circuit, and the mixer circuit in the second mode.

6. The communication chip of claim 1, wherein the digital baseband circuit disables the DAC and the filter circuit in the second mode.

7. A communication chip configured to transmit a radio frequency (RF) output signal or receive an RF input signal, comprising:
an impedance matching circuit;
a pin coupled to the impedance matching circuit;
a digital baseband circuit configured to generate a control signal and a digital output signal;
a reference signal generation circuit coupled to the digital baseband circuit and configured to generate a reference signal;
a digital-to-analog converter (DAC) coupled to the digital baseband circuit and configured to convert the digital output signal into an analog output signal;
a filter circuit coupled to the DAC and configured to filter the analog output signal to generate a filtered analog output signal;
a transmitter front-end circuit coupled to the filter circuit and the impedance matching circuit and configured to process the filtered analog output signal or the reference signal to generate the RF output signal, and transmit the RF output signal through the impedance matching circuit and the pin; and
a receiver circuit coupled to the impedance matching circuit and configured to receive the RF input signal through the pin and the impedance matching circuit.

8. The communication chip of claim 7, wherein when the communication chip operates in a first mode, the reference signal is a single tone signal; and when the communication chip operates in a second mode, the reference signal generation circuit changes a frequency of the reference signal according to the control signal.

9. The communication chip of claim 8, wherein the transmitter front-end circuit comprises:
a mixer circuit coupled to the filter circuit and configured to up-convert the filtered analog output signal to generate an RF signal;
a power amplifier driver (PAD) coupled to the mixer circuit and comprising:
a first sub-PAD coupled to the mixer circuit and configured to amplify the reference signal; and
a second sub-PAD coupled to the mixer circuit and configured to amplify the RF signal;
a power amplifier; and
a transformer coupled between the PAD and the power amplifier.

10. The communication chip of claim 9, wherein the digital baseband circuit disables the DAC, the filter circuit, and the mixer circuit in the second mode.

11. The communication chip of claim 8, wherein the digital baseband circuit disables the DAC and the filter circuit in the second mode.

12. An electronic device configured to transmit a radio frequency (RF) output signal or receive an RF input signal, comprising:
an antenna; and
a communication chip comprising:
a pin electrically connected to the antenna;
an impedance matching circuit coupled to the pin;
a digital baseband circuit;
a reference signal generation circuit coupled to the digital baseband circuit;
a transmitter circuit coupled to the digital baseband circuit, the reference signal generation circuit, and the impedance matching circuit and configured to generate the RF output signal; and
a receiver circuit coupled to the digital baseband circuit, the reference signal generation circuit, and the impedance matching circuit and configured to process the RF input signal;
wherein the communication chip transmits the RF output signal through the pin, or receives the RF input signal through the pin.

13. The electronic device of claim 12, wherein the digital baseband circuit generates a control signal and a digital output signal, the control signal controls the reference signal generation circuit to generate a reference signal, and the transmitter circuit comprises:
a digital-to-analog converter (DAC) coupled to the digital baseband circuit and configured to convert the digital output signal into an analog output signal;
a filter circuit coupled to the DAC and configured to filter the analog output signal to generate a filtered analog output signal; and
a transmitter front-end circuit coupled to the filter circuit;
wherein when the communication chip operates in a first mode, the transmitter front-end circuit up-converts and amplifies the filtered analog output signal according to the reference signal to generate the RF output signal; and
wherein when the communication chip operates in a second mode, the reference signal generation circuit changes a frequency of the reference signal according to the control signal, and the transmitter front-end circuit amplifies the reference signal to generate the RF output signal.

14. The electronic device of claim 13, wherein when the communication chip operates in the first mode, the reference signal is a single tone signal.

15. The electronic device of claim 13, wherein the transmitter front-end circuit comprises:
a mixer circuit coupled to the filter circuit and configured to up-convert the filtered analog output signal to generate an RF signal;
a power amplifier driver (PAD) coupled to the mixer circuit and comprising:
a first sub-PAD coupled to the mixer circuit and configured to amplify the reference signal; and
a second sub-PAD coupled to the mixer circuit and configured to amplify the RF signal;
a power amplifier; and
a transformer coupled between the PAD and the power amplifier.

16. The electronic device of claim 15, wherein the digital baseband circuit disables the DAC, the filter circuit, and the mixer circuit in the second mode.

17. The electronic device of claim 13, wherein the digital baseband circuit disables the DAC and the filter circuit in the second mode.
